(19) United States
(12) Patent Application Publication
(10) Pub. No.: US 2009/0236636 A1
(43) Pub. Date: Sep. 24, 2009

(54) Closed Cell Array Structure Capable of Decreasing Area of non-well Junction Regions

(76) Inventor: Hsiu-Wen Hsu, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 12/127,805

(22) Filed: May 27, 2008

(30) Foreign Application Priority Data
Mar. 20, 2008 (TW) 097109837

(51) Int. Cl. H01L 29/76

(52) U.S. Cl. 257/202; 257/E29.226

(57) ABSTRACT

A closed cell array structure capable of decreasing area of non-well junction regions includes a plurality of closed cell units, arranged in a plane, each shaped as a polygon, and a plurality of gate windows, each formed in a corner of a closed cell unit in a gate layer without doped source ion material.

### BACKGROUND OF THE INVENTION

1. Field of the Invention

The present invention relates to a closed cell array structure capable of decreasing area of non-well junction regions, and more particularly, to a closed cell array structure having gate windows without doped source ion material at corners, in order to decrease area of non-well junction regions and decease gate charges and conduction resistance.

2. Description of the Prior Art

In prior art, power Metal Oxide Semiconductor Field Effect Transistor (MOSFET) is an insulate-gate voltage-controlled unipolar unit with high input impedance and high switching speed, and is applicable for power systems operating in middle or low voltage, such as inverter control switches, DC-DC converters, etc., due to low Ron (conducting resistance) and switching dissipation, and wide operating region.

As for manufacturing of power MOSFET, the prior art has provided multiple deigns of cell masks, such as striped cell, closed cell, etc. The structure of the striped cell is line-shaped, and the corresponding schematic diagram and cross-section view diagram are shown in FIG. 1 and FIG. 2. The closed cell is formed by units with a specific shape, such as triangle, square, hexagon, etc. FIG. 3 and FIG. 4 show a schematic and cross-section view diagrams of a square cell.

Comparing the striped cell and the closed cell, it can be known that since a gate region of a power MOS of the striped cell is smaller than that of the closed cell, Cgd (gate-drain capacitance) of the power MOS of the striped cell is smaller than that of the closed cell, so that Qgd (gate-drain charge) is smaller. However, since channel width and regions of Junction Field Effect Transistor (JFET) become smaller, such that, under the same epitaxial condition, Ron of the striped cell is larger than that of closed cell. Although the closed cell has lower Ron than the striped cell, the closed cell has spherical junctions in corners, leading to lower blocking voltage. Please refer to FIG. 5 and FIG. 6. FIG. 5 and FIG. 6 illustrate schematic diagrams of the spherical junctions. The spherical junctions are junctions between spherical regions and cylindrical regions, where the spherical regions are formed on the corners of a chip after a diffusion step due to covering of square masks. Since the effect of electric-field crowding near the spherical regions are stronger than that of the cylindrical regions, the blocking voltage of the closed cell is lower than that of the striped cell. Due to the lower blocking voltage, the closed cell cannot be applicable for high-level epitaxy or doped high-level JFET ions to decrease Ron. Therefore, under the requirement of the same blocking voltage, the striped cell can reach lower Ron.

### SUMMARY OF THE INVENTION

It is therefore a primary objective of the claimed invention to provide a closed cell array structure capable of decreasing area of non-well junction regions.

The present invention discloses a closed cell array structure capable of decreasing area of non-well junction regions, which comprises a plurality of closed cell units, arranged in a plane, each shaped as a polygon, and a plurality of gate windows, each formed in a corner of a closed cell unit in a gate layer without doped source ion material.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a schematic diagram of a striped cell.

FIG. 2 shows a cross-section view diagram of a striped cell.

FIG. 3 shows a schematic diagram of a square cell.

FIG. 4 shows a cross-section view diagram of a square cell.

FIG. 5 and FIG. 6 illustrate schematic diagrams of spherical junctions.

FIG. 7 illustrates a schematic diagram of a closed cell array structure according to an embodiment of the present invention.

FIG. 8 illustrates a single closed cell unit according to an embodiment of the present invention.

FIG. 9 and FIG. 10 are cross-section diagrams of the closed cell array structure shown in FIG. 7 along different points.

FIG. 11 and FIG. 12 show schematic diagrams of a hexagon-shaped closed cell array structure and the corresponding closed cell unit.

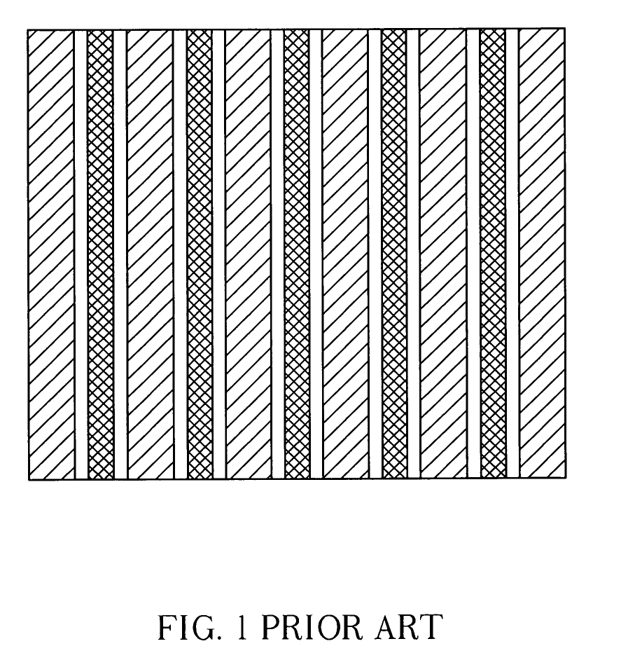

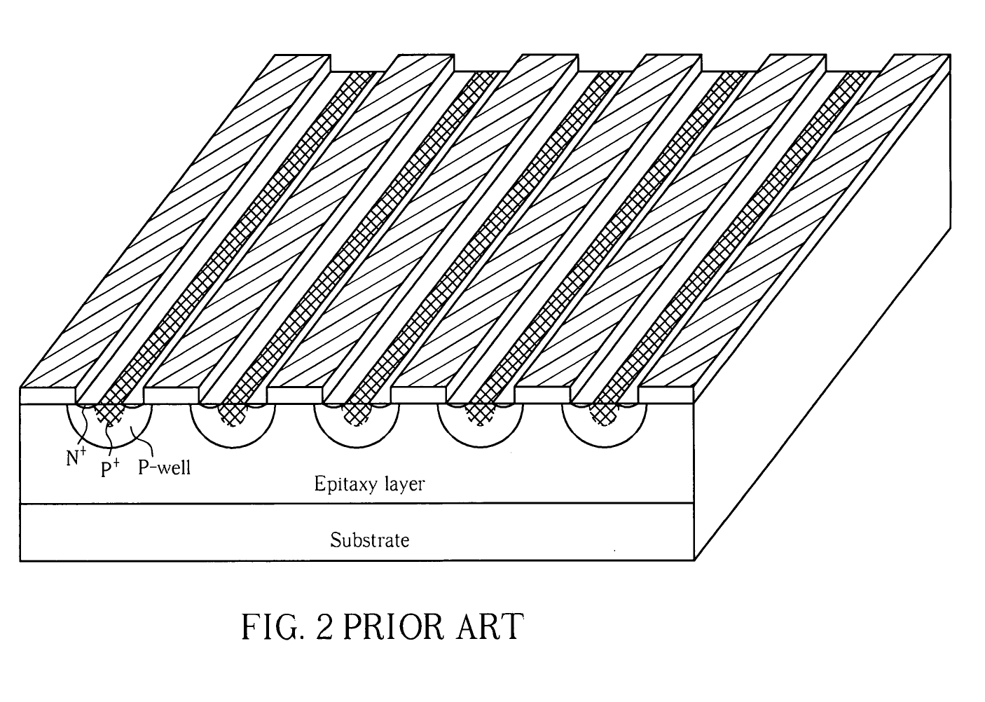

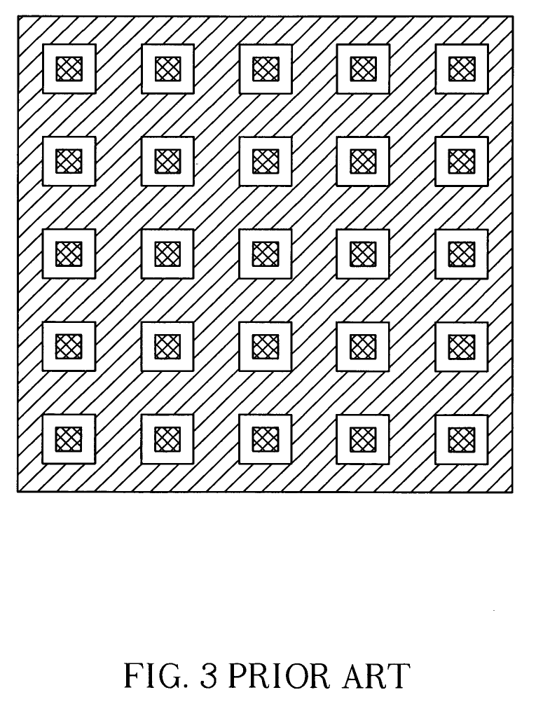

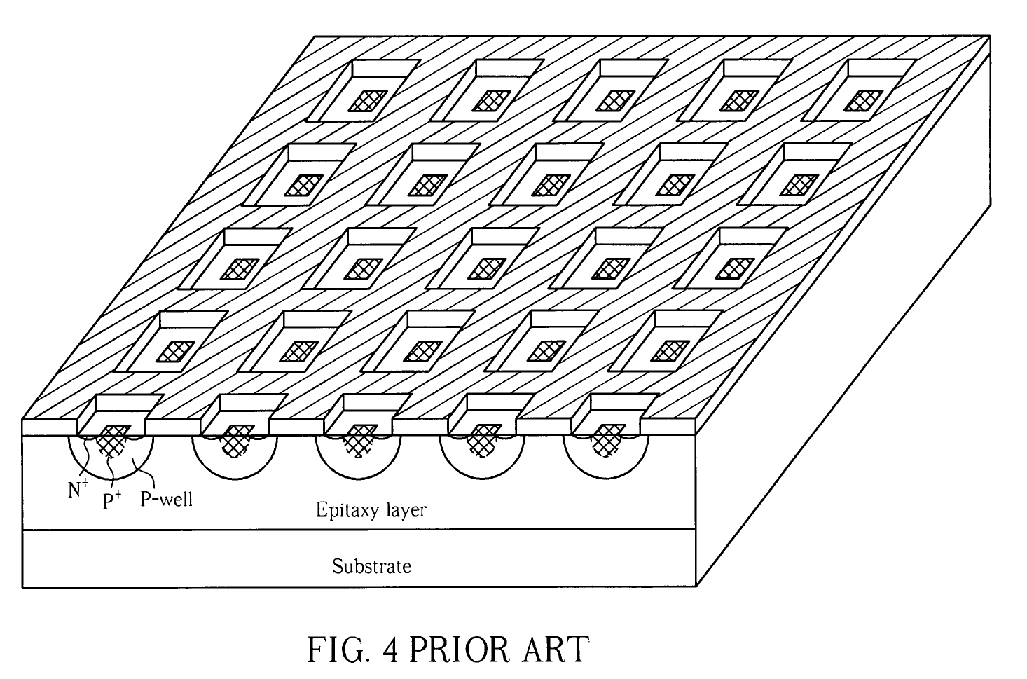

### DETAILED DESCRIPTION

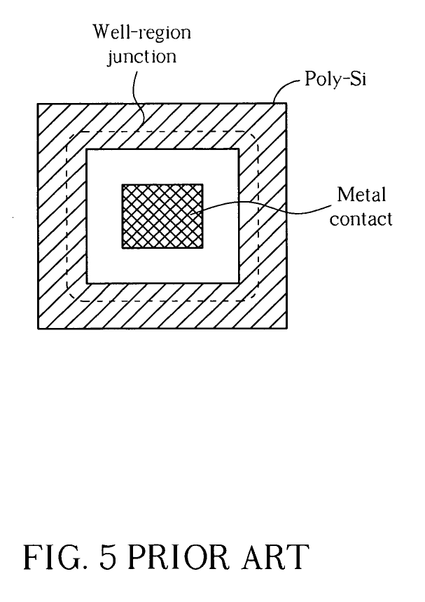

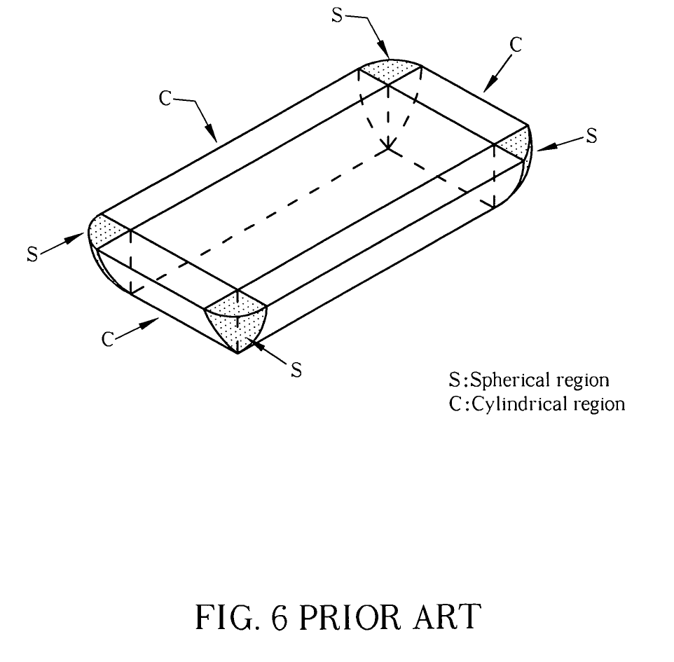

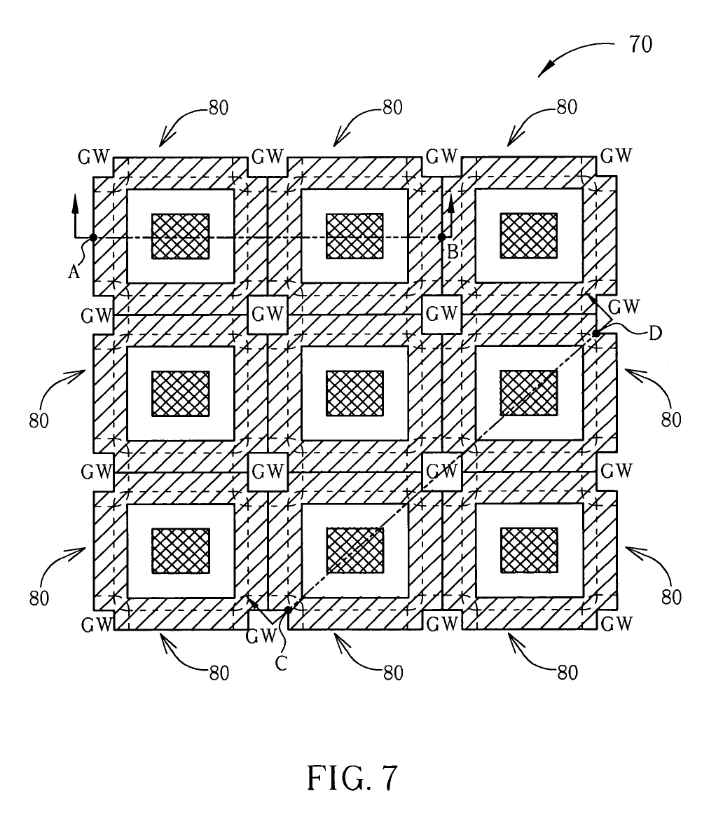

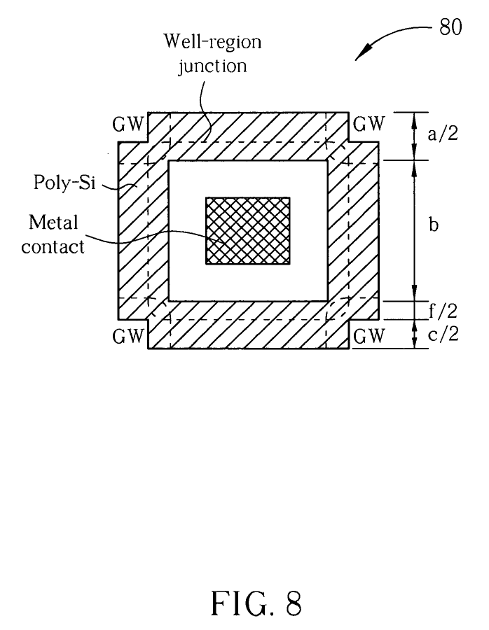

Please refer to FIG. 7, which illustrates a schematic diagram of a closed cell array structure 70 according to an embodiment of the present invention. The closed cell array structure 70 can decrease area of non-well junction regions, and is preferably utilized for a power MOSFET. The closed cell array structure 70 comprises a plurality of closed cell units 80 and a plurality of gate windows GW. Please refer to FIG. 8, which illustrates a single closed cell unit 80 according to an embodiment of the present invention. The closed cell unit 80 is similar to the unit cell shown in FIG. 5 except that the closed cell unit 80 comprises gate windows GW without doped source ion material at four corners. In other words, when defining a gate layer, the present invention forms a gate window GW at each of the four corners, and does not dope source ion material by covering of masks when performing sources ion implantation.

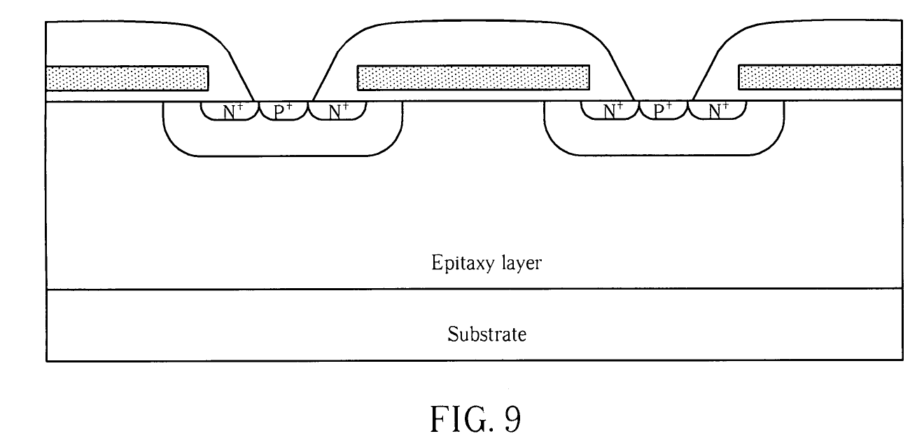

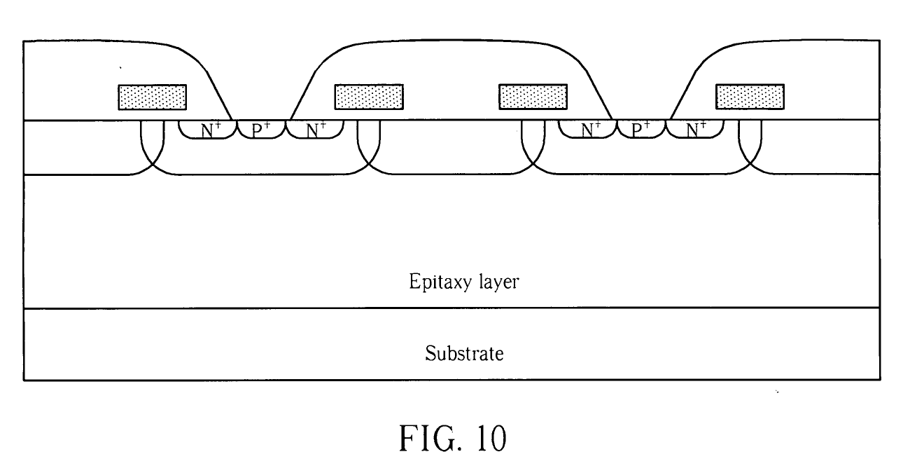

Please refer to FIG. 9 and FIG. 10. FIG. 9 and FIG. 10 are cross-section diagrams of the closed cell array structure 70 along points A and B, and along points C and D. For clarity, metal layers, protection layers, etc. are omitted from FIG. 9 and FIG. 10. As shown in FIG. 10, since the gate windows GW are not doped source ions, the gate windows GW form junctions of well regions with non-gate regions when performing steps of ion implantation and diffusion on the well regions, so that there are no spherical junctions at the corners due to the extra junctions of well regions. As a result, Ron can be optimized by decreasing resistance of epitaxy or increasing level of JFET ions. Meanwhile, since channel width and regions of JFET are larger than the striped cell, much lower Ron can be gained.

Besides, since the gate windows GW form the extra junctions of well regions, area of non-well junction regions in gate regions become smaller than that in the conventional closed cell as shown in FIG. 5, so as to reach small gate charges, and gain better FOM (Figure Of Merit) of Ron and Qgd. Take the prior art square closed cell unit for example, if the gate width is a, the distance between gates is b, the length of lateral diffusion injunction of well-region is f/2, then the area of non-well junction region in the prior art square cell unit is: (a+b)²−(b+f)²+f²−πf²/4; and the area of non-well junction region in the prior art striped cell unit is: 2(a/2−f/2)(a+b). Under the same condition, in the present invention, if the side length of the gate window GW is c, the area of non-well junction region in the closed cell unit 80 is: 4(a/2−f/2)(a+b−c−f). Suppose a=12 um, b=12 um, c=9.4 um, and f=3.6 um. The area of non-well junction region in the prior art square cell unit is 335 um². The area of non-well junction region in the prior art striped cell unit is 202 um². The area of non-well junction region in the closed cell unit 80 is 185 um². Therefore, the present invention can efficiently decrease area of non-well junction regions, to decrease gate charges.

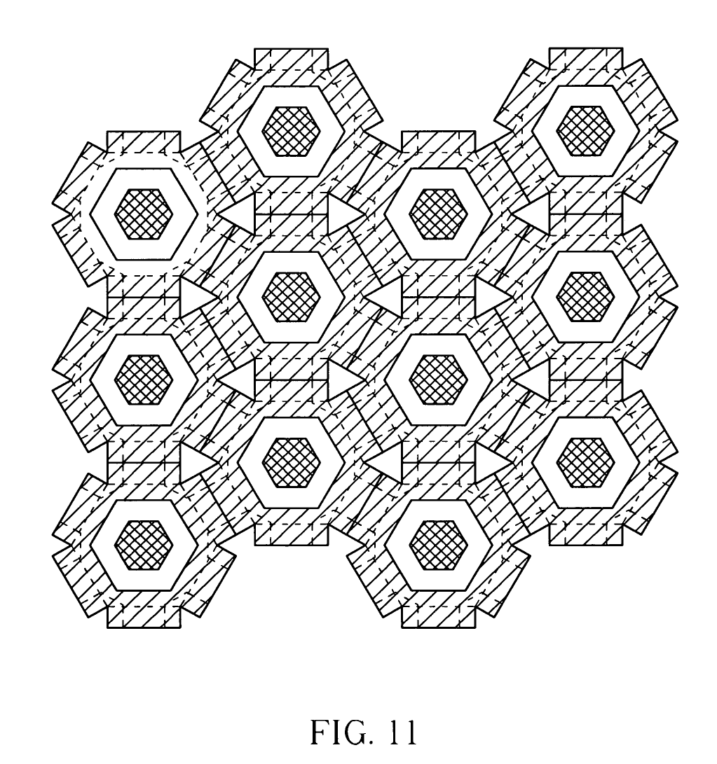

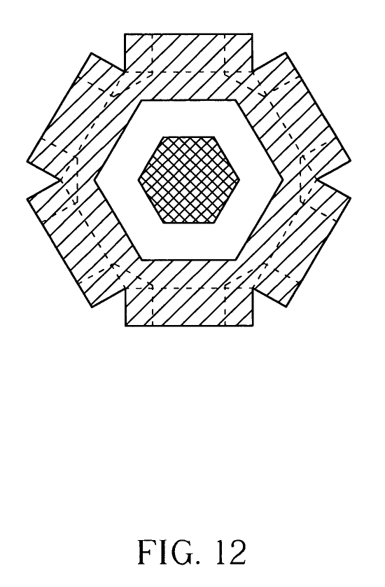

Note that, in FIG. 7 and FIG. 8, the closed cell unit 80 is square-shaped. In fact, other shapes are applicable for the present invention. For example, FIG. 11 and FIG. 12 show schematic diagrams of a hexagon-shaped closed cell array structure and the corresponding closed cell unit.

In summary, the present invention forms gate windows without doped source ion material at corners in the closed cell unit, so that there are no spherical junctions at the corners due to the extra junctions of well regions formed with the gate windows, in order to decrease area of non-well junction regions and decease gate charges and Ron.

Those skilled in the art will readily observe that numerous modifications and alterations of the device and method may be made while retaining the teachings of the invention.

What is claimed is:

1. A closed cell array structure capable of decreasing area of non-well junction regions comprising:
a plurality of closed cell units, arranged in a plane, each shaped as a polygon; and
a plurality of gate windows, each formed in a corner of a closed cell unit in a gate layer without doped source ion material.

2. The closed cell array structure of claim 1, wherein each of the plurality of gate windows forms a junction of well region with non-gate regions when performing steps of ion implantation and diffusion on the well regions.

3. The closed cell array structure of claim 1, wherein each of the plurality of gate windows is formed via masks.

4. The closed cell array structure of claim 1, wherein each of the plurality of closed cell units is shaped as a quadrangle.

5. The closed cell array structure of claim 1, wherein each of the plurality of closed cell units is shaped as a hexagon.

6. The closed cell array structure of claim 1 being utilized for a power metal oxide semiconductor field effect transistor.
